(19) United States
(12) Patent Application Publication
(10) Pub. No.: US 2025/0038077 A1
(43) Pub. Date: Jan. 30, 2025

(54) ELECTRONIC DEVICE WITH LEAD LOCK

(71) Applicant: TEXAS INSTRUMENTS INCORPORATED, DALLAS, TX (US)

(72) Inventors: CHU-YUN LO, Taipei City (TW); MEGAN CHANG, Taipei City (TW); YUH-HARNG CHIEN, New Taipei City (TW)

(21) Appl. No.: 18/360,873

(22) Filed: Jul. 28, 2023

(51) Int. Cl. H01L 23/495

(52) U.S. Cl. CPC H01L 23/49524; H01L 23/49544; H01L 23/49548; H01L 23/49575

(57) ABSTRACT

An electronic device includes a leadframe having a die pad, inner leads, and outer leads. The die is attached to the die pad, where the die includes an active side. Lead locks are disposed adjacent to the inner leads. The lead locks include a side support disposed on each side of the inner leads and an opening defined between each side support and the inner leads. Wire bonds are attached from the active side of the die to the inner leads and a mold compound is formed to encapsulate the die, the inner leads, the lead locks, and the wire bonds.

### TECHNICAL FIELD

The present disclosure relates to an electronic device and more specifically, to an integrated circuit package having a lead lock.

### BACKGROUND

Integrated circuit (IC) packages are encapsulated with a mold compound for protection. In addition, wire bonds inside the mold compound provide a connection from a die of the IC package to the outside world such a printed circuit board via leads. However, wire bond disconnection and leadframe lead delamination have the potential risk of creating open circuits between the wire bonds that are connected from the die to leads of the leadframe during a curing heating process. The cause of this phenomena is a coefficient of thermal expansion (CTE) mismatch between the leads and a mold compound during the curing process. The CTE mismatch creates high thermal stresses between the leads and the mold compound. The stresses result in a delamination force on the surface of the leads, which causes the mold compound to fracture or pull away from the leads. As a result, a lamination layer deposited on the leads also fractures or pulls away from the leads due to the delamination force created by the fracture of the mold compound. Consequently, the lamination layer pulls the wire bonds away from the leads thereby disconnecting the wire bond from the leads causing the open circuit.

### SUMMARY

In described examples, an electronic device includes a leadframe having at least one die pad, inner leads, and outer leads. At least one die is attached to the at least one die pad, where the at least one die including an active side. Lead locks are disposed adjacent to the inner leads. The lead locks include a side support disposed on each side of the inner leads and an opening defined between each side support and the inner leads. Wire bonds are attached from the active side of the plurality of dies to the inner leads and a mold compound is formed to encapsulate the plurality of dies, the inner leads, the lead locks, and the wire bonds.

In still another described example, a method includes providing a leadframe, where the leadframe includes lead locks including side supports disposed on each side of inner leads of the leadframe. A first end of the side supports is connected to a cross bar of the inner lead and a second end of the side supports being connected to a dam bar. The side supports are partially etched to form a recess between the first end to the second end of the side supports. At least one die is attached to at least one die pad and wire bonds are attached from an active layer of the at least one die to the inner leads of the leadframe. A molding compound is formed over the at least one die, the at least one die pad, the lead locks, and the wire bonds.

In still another described example, a multi-chip integrated circuit includes a leadframe having a plurality of die pads, inner leads, and outer leads. The circuit further includes a plurality of dies, where a die of the plurality of dies is attached to each die pad of the plurality of die pads, where each of the plurality of dies has an active side. Lead locks are disposed adjacent to the inner leads, where the lead locks have a side support disposed on each side of the inner leads and an opening defined between each side support and the inner leads. Wire bonds are attached from the active side of each of the plurality of dies to the inner leads and a mold compound encapsulates the plurality of dies, the inner leads, the lead locks, and the wire bonds.

### BRIEF DESCRIPTION OF THE DRAWINGS

FIG. 1A illustrates a top perspective view of an example electronic device.

FIG. 1B illustrates a top view of the example electronic device in FIG. 1A.

FIG. 1C illustrated a cross-sectional view of the example electronic device in FIGS. 1A and 1B.

FIG. 1D illustrates a side view of the example electronic device of FIGS. 1A and 1B.

FIGS. 1E, 1F, and 1G illustrate a perspective view, a top view, and a side view respectively of a lead lock of the example electronic device in FIGS. 1A-1D.

FIG. 2 is a top view of an example leadframe and dies illustrating a die area of the example electronic device in FIGS. 1A-1D.

FIG. 3 is a top view of an example leadframe and dies illustrating a die area of another example electronic device.

FIG. 4 is a block diagram illustration of a fabrication process for the electronic devices illustrated in FIGS. 1A-1D.

FIGS. 5A and 5B illustrate a top view and a cross-sectional view taken at line 5B-5B respectively of an electronic device in the early stages of fabrication.

FIGS. 5C and 5D illustrate a top view and a cross-sectional view taken at line 5D-5D respectively of the electronic device of FIGS. 5A and 5B after a partial etching process.

FIGS. 5E and 5F illustrate a top view and a cross-sectional view taken at line 5F-5F respectively of the electronic device of FIGS. 5C and 5D after attachment of a die(s).

FIGS. 5G and 5H illustrate a top view and a cross-sectional view taken at line 5H-5H respectively of the electronic device of FIGS. 5E and 5F after attachment of wire bonds.

FIGS. 51 and 5J illustrate a top view and a cross-sectional view taken at line 5J-5J respectively of the electronic device of FIGS. 5G and 5H after formation of a mold compound.

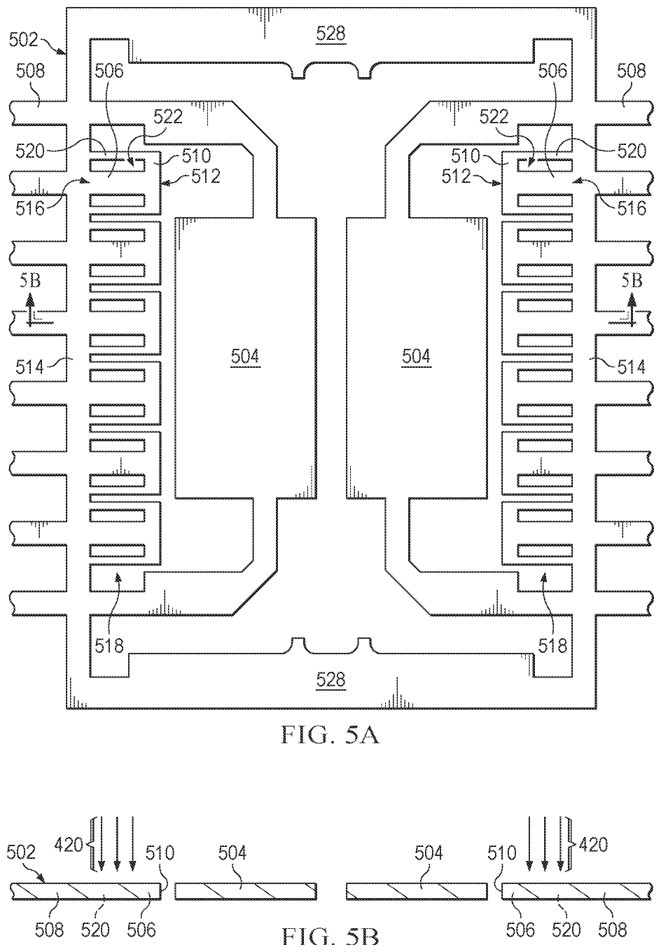

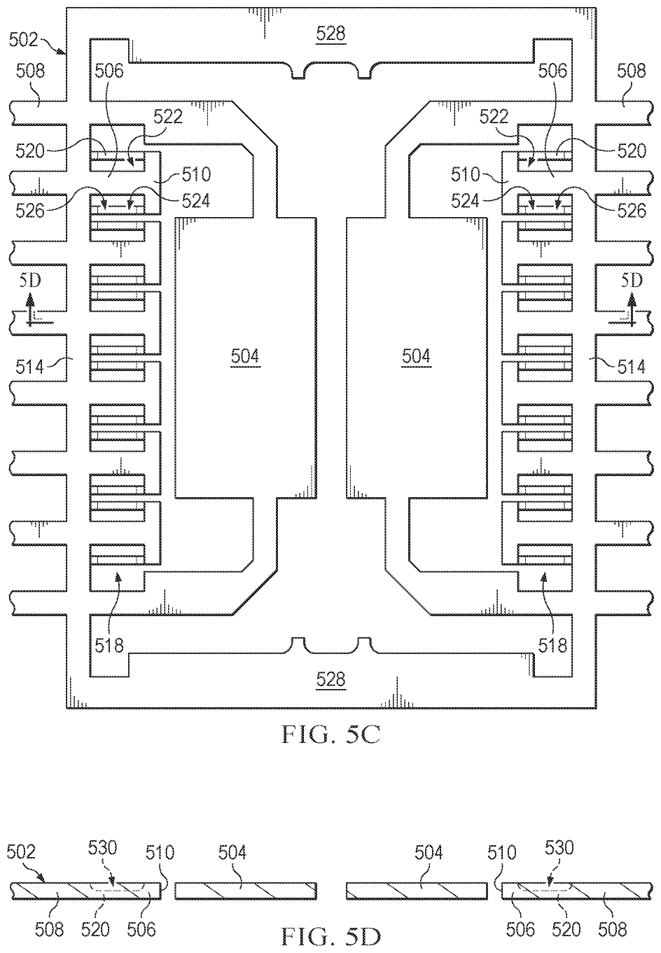

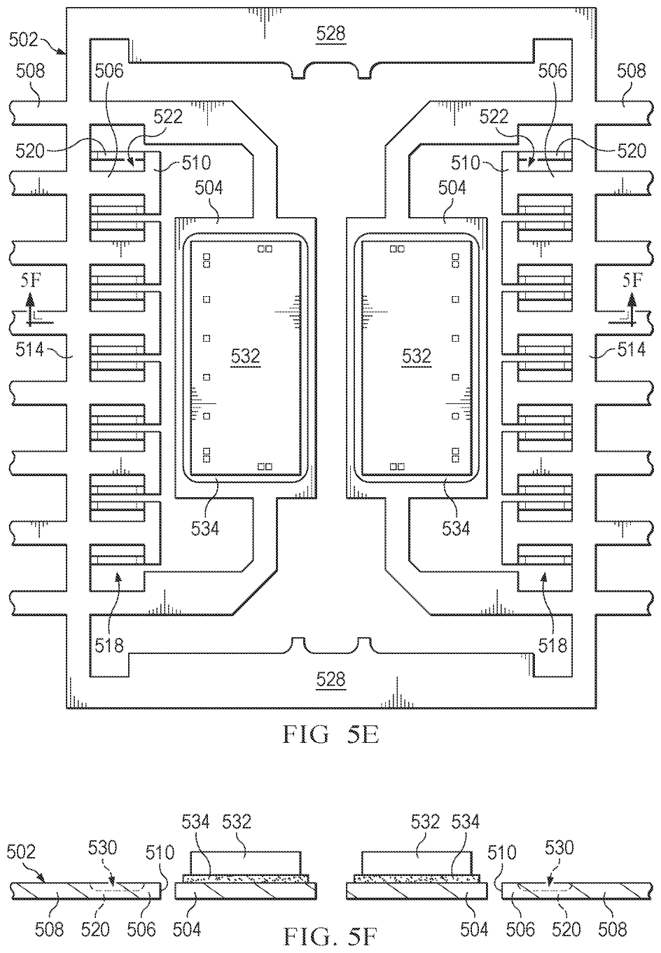

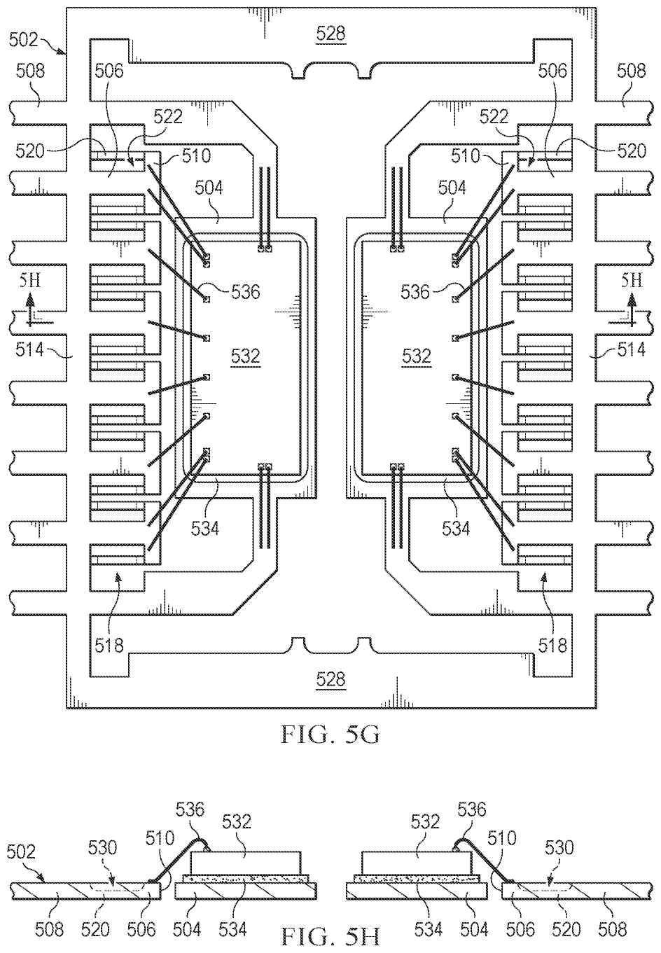

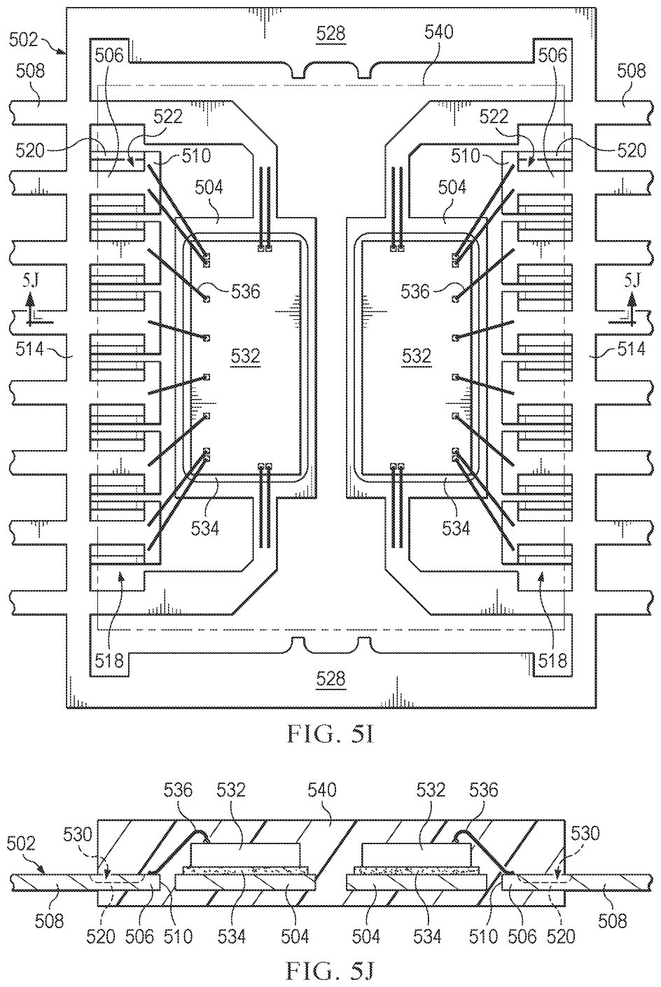

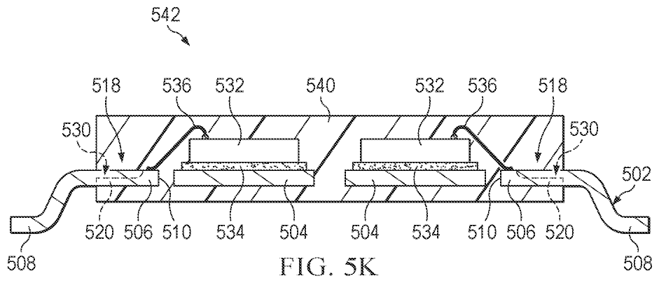

FIG. 5K illustrates a cross-sectional view of the electronic device of FIGS. 51 and 5J after shaping of outer leads and singulation.

### DETAILED DESCRIPTION

In integrated circuit (IC) packages, delamination creates a potential of forming open circuits in the IC package. Specifically, a delamination force on a surface of the leads of a leadframe causes a mold compound to fracture or pull away from the leads. As a result, a lamination layer deposited on the leads also fractures or pulls away from the leads. Consequently, the lamination layer pulls the wire bonds away from the leads thereby disconnecting the wire bonds from the leads causing the open circuit. The cause of this phenomena is a coefficient of thermal expansion (CTE) mismatch between the leads and the mold compound during the curing process. The CTE mismatch creates high thermal stresses between the leads and the mold compound, thereby resulting in the delamination force.

Disclosed herein is an example integrated circuit package that reconfigures a lead lock (mold lock) to overcome the aforementioned disadvantages. Specifically, the IC package includes a fence type lead lock configuration comprised of partially etched side supports and openings defined adjacent to the side supports. The partially etched side supports are disposed on each side of each lead of a leadframe and are substantially parallel with each lead. The openings are defined between each partially etched side support and the inner leads. The etched portion of the partially etched side supports and the openings increase a contact area with a mold compound to resist the delamination force during a curing process thereby overcoming the aforementioned disadvantages. In addition, the fence type lead lock configuration creates a larger die space area, which results in the use of larger dies in the IC package.

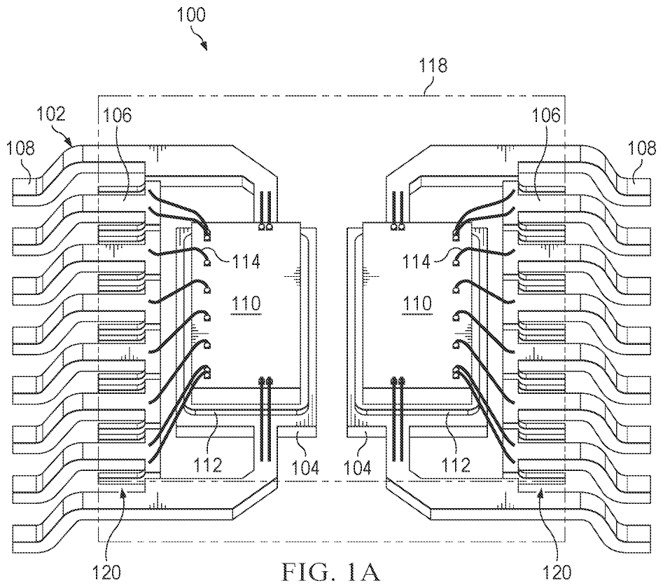

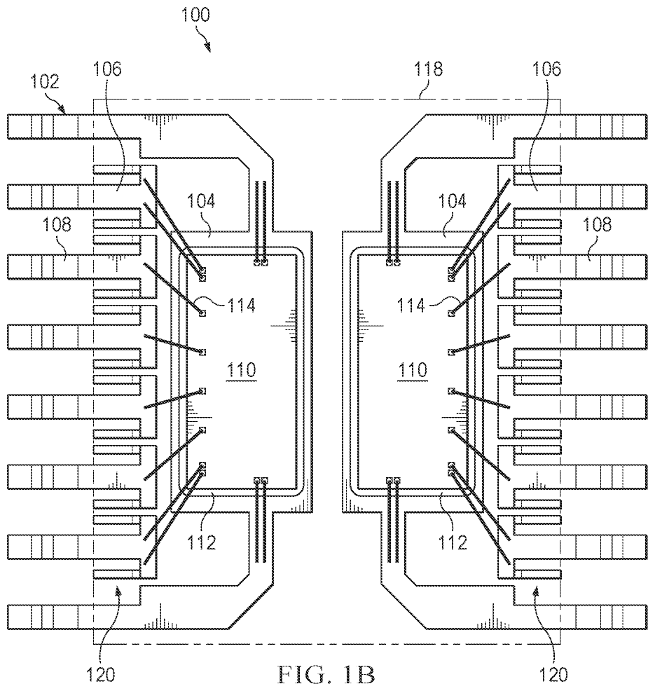

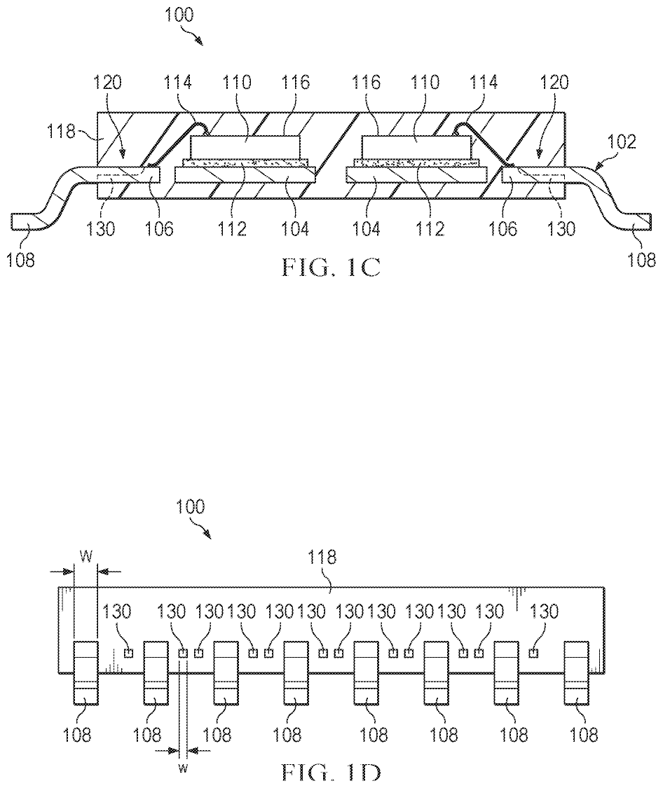

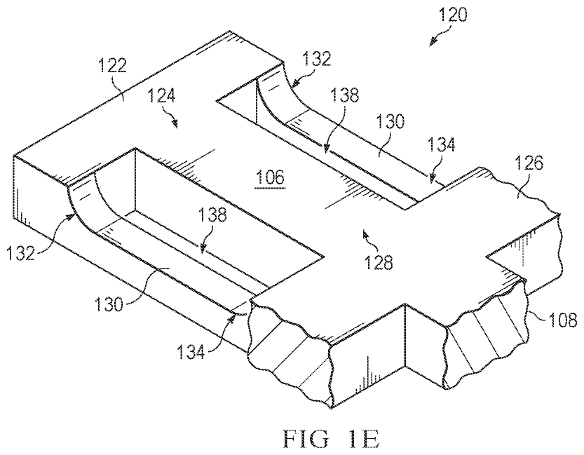

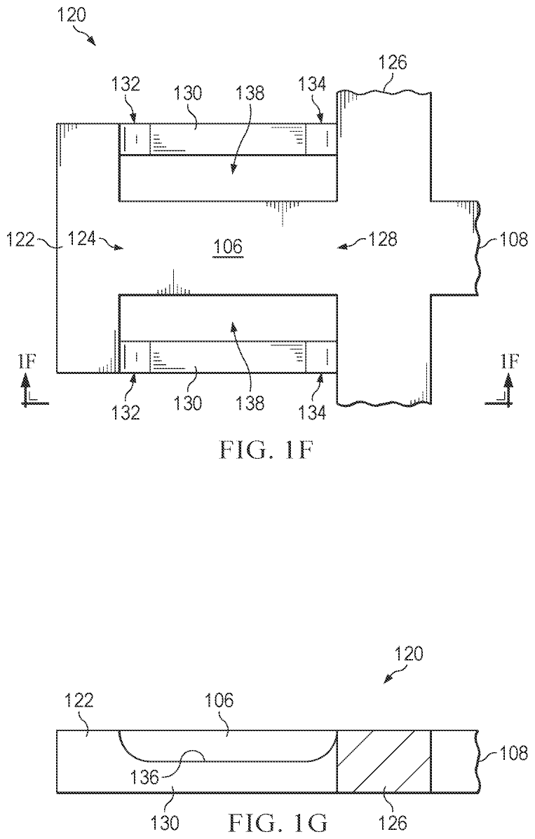

FIG. 1A is a top perspective view, FIG. 1B is a top view, FIG. 1C is a cross-sectional view and FIG. 1D is a side view of an example electronic device (e.g., integrated circuit (IC) package) 100. The example illustrated in FIGS. 1A-1D is a dual in-line, multi-chip IC package. The electronic device 100, however, can be comprised of leaded or non-leaded IC packages. Some other example IC packages may include, a double in-line package (DIP), a single in-line package (SIP), a small outline package (SOP), a quad flat no-lead (QFN) package, a quad flat package (QFP), etc. Thus, the example illustrated in FIGS. 1A-1D is for illustrative purposes only and is not intended to limit the scope of the invention.

The electronic device 100 includes a leadframe 102 including a die pad 104 and leads comprised of inner leads 106 and outer leads 108. A die 110 is attached to the die pad 104 of the leadframe 102 via a die attach material 112. Wire bonds 114 are connected from an active side 116 of the die 110 to the inner leads 106. A mold compound 118 is formed over and encapsulates the die 110, the wire bonds 114, and the inner leads 106. In addition, in other examples, the mold compound 118 covers all but one surface of the leadframe 102, where the one surface not covered faces away from the die 110 and the electronic device 100.

Still referring to FIGS. 1A-1D and also to FIGS. 1E-1G, the leadframe 102 further includes lead locks 120. As mentioned above, the configuration of the lead locks 120 increases a contact area between the inner leads 106 and the mold compound 118, which relieves thermal stresses between the inner leads 106 and the mold compound 118. The inner leads 106 include a cross bar 122 integrated at a first (proximate) end 124. The cross bar 122 is substantially perpendicular to the inner leads 106. Thus, the inner leads 106 and cross bar 122 form a T-shape. The inner leads 106 are connected to the outer leads 108 and a dam bar 126 at a second (distal) end 128. The dam bar 126 is removed during fabrication after formation and curing of the mold compound 118.

The lead locks 120 include side supports 130 disposed on opposite sides of the inner leads 106 and are substantially parallel with the inner leads 106. The side supports 130 are connected to the cross bar 122 at a first (proximate) end 132 and the dam bar 126 at a second (distal or terminal) end 134. The side supports 130 are partially etched between the first end 132 and the second end 134 to thereby form a recess 136 between the first and second ends 132, 134. As illustrated in FIGS. 1B and 1D, after removal of the dam bar 126, the second end 134 of the side supports 130 is substantially flush with the mold compound 118 and is thus exposed. In addition, a width w of the side supports 130 is less than a width W of the outer leads 108.

Openings 138 are defined between each of the side supports 130 and the inner leads 106. The openings 138 can have any shape (e.g., circular, oval, square, rectangular, etc.) based on a configuration of the leadframe 102. During formation of the mold compound 118, the mold compound 118 is deposited in the recess 136 and the openings 138 such that the mold compound 118 flows through the openings 138 and encapsulates the side supports 130 and the inner leads 106. The formation of the mold compound 118 in the openings 138 creates a mold lock. Specifically, the mold compound 118 flows into the recess 136 and through the openings 138 thereby surrounding the side supports 130 and the inner leads 106. When cured, the mold compound 118 adheres to itself, the side supports 130, and the inner leads 106 to create a mold lock, which increases an adhesion strength of the mold compound 118, thereby creating a stronger bond. Thus, when the mold compound 118 is cured, the stronger bond reduces the delamination force.

As illustrated in the figures, the lead locks 120 are adjacent and connected to each inner lead 106. In an alternative example, the lead locks 120 can be connected to a select few inner leads 106 (e.g., every other, every third, or another pattern, etc.). In still another alternative example, in electronic devices where a reduction in spacing between adjacent leads is desired, the lead locks can include a single side support disposed on one side of the inner lead. In this example, the inner lead can include a half cross bar to thereby form an L-shape (as opposed to the T-shape). Thus, the first end of the single side support is connected to the half cross bar and the second end of the single side support is connected to the dam bar. The lead lock further includes an opening, as described above, defined between the inner lead and the single side support.

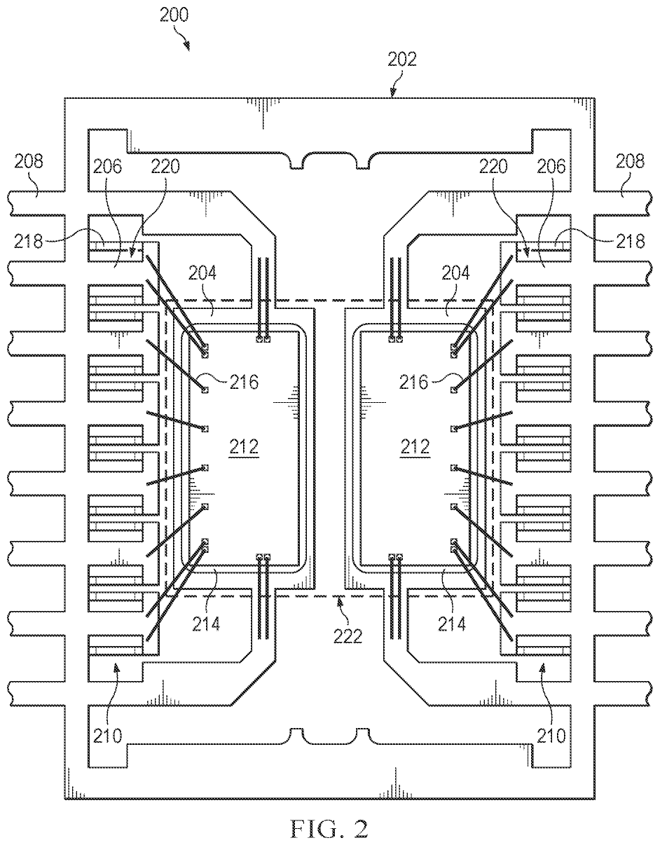

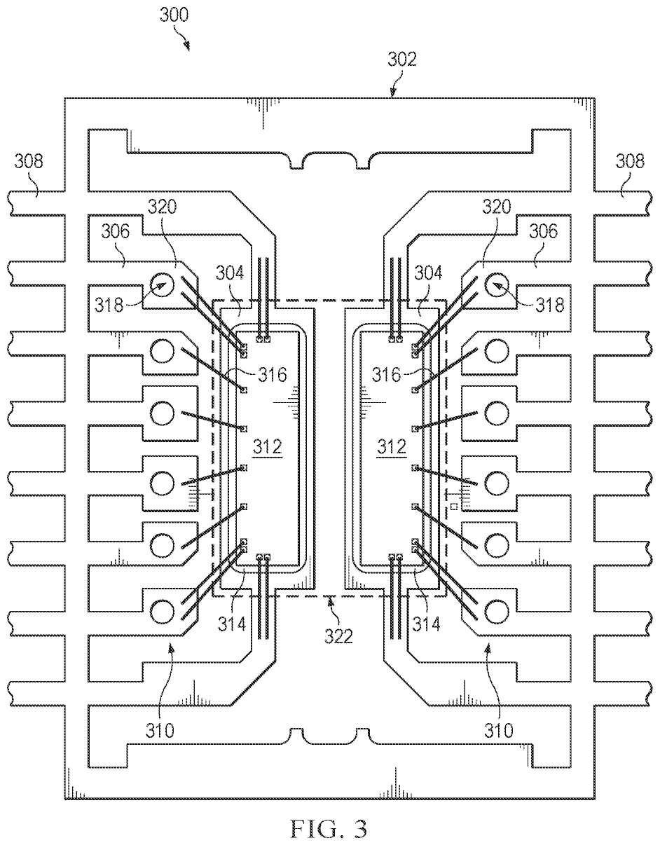

Referring FIGS. 2 and 3, FIG. 2 is a top view of an example electronic device 200 prior to formation of a mold compound. The electronic device 200 can correspond to the electronic device 100 in the example illustrated in FIGS. 1A-1D. Thus, any reference is to be made to the example in FIGS. 1A-1D in the following description of the example in FIG. 2. Although the example illustrates a multi-die configuration, explanation with respect to one die will be described herein for simplicity. The electronic device 200 includes a leadframe 202 having a die pad 204, inner leads 206, outer leads 208, and lead locks 210. A die 212 is attached to the die pad 204 via a die attach material 214. Wire bonds 216 are attached from the die 212 to the inner leads 206. The lead locks 210 include side supports 218 that are partially etched and openings 220 defined between the side supports 218 and the inner lead 206, as described above and illustrated in FIG. 1E. A die pad area (represented by the dotted line) 222 is centrally defined in the leadframe 202.

Similarly, FIG. 3 is a top view of another example electronic device 300 prior to formation of a mold compound. Although the example illustrates a multi-die configuration, explanation with respect to one die will be described herein for simplicity. The electronic device 300 includes a leadframe 302 having a die pad 304, inner leads 306, outer leads 308, and lead locks 310. A die 312 is attached to the die pad 304 via a die attach material 314. Wire bonds 316 are attached from the die 312 to the inner leads 306. The lead locks 310 in this example, however, include openings 318 defined in a wire bonding portion 320 of the inner leads 306. As illustrated in FIG. 3, the wire bonding portion 320 extends from an end of the inner leads 306 opposite that of the outer leads 308, and is enlarged to accommodate the opening 318. As a result, a size of a die pad area (represented by the dashed box) 322 is limited due to the enlarged bonding portion 320.

Comparing the example leadframe 202 in FIG. 2 and the leadframe 302 in FIG. 3, the size of the die pad area 222 in FIG. 2 is larger than the size of the die pad area 322 in FIG. 3. This is due to the configuration of the lead locks 210 in FIG. 2. Specifically, the lead locks 210 in FIG. 2 are disposed on either side of the inner leads 206 (also illustrated in FIGS. 1A and 1B). On the other hand, the lead locks 310 in FIG. 3 are attached to an end of the inner leads 306 and thus, extend toward the die pad area 322, thereby decreasing the size of the die pad area 322. As a result, the leadframe 202 in FIG. 2 can accommodate larger dies without increasing an overall size of the electronic device. Thus, the leadframe 202 illustrated in FIG. 2 has a superior configuration that accommodates larger dies and enhances delamination protection due to an increase in surface area for the mold lock.

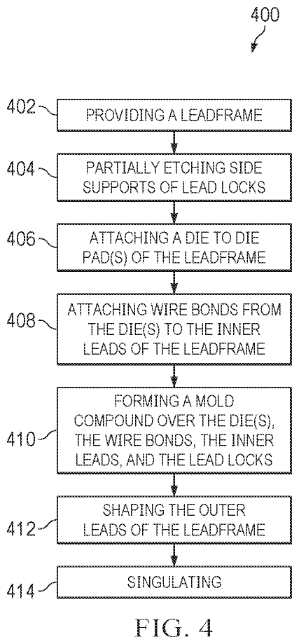

FIG. 4 is a block diagram flow chart explaining a fabrication process 400 and FIGS. 5A-5G illustrate the fabrication process associated with the formation of the electronic device 100 illustrated in FIGS. 1A-1D. Though depicted sequentially as a matter of convenience, at least some of the actions shown can be performed in a different order and/or performed in parallel. Alternatively, some implementations may perform only some of the actions shown. Still further, although the example illustrated in FIGS. 4 and 5A-5G is an example method illustrating the example configuration of FIGS. 1A-1D, other methods and configurations are possible. It is understood that although the method illustrated in FIGS. 4 and 5A-5G illustrates the fabrication process of a single electronic device, the process applies to an array of electronic devices. Thus, after fabrication of the array of electronic devices the array is singulated to separate each electronic device from the array.

Referring to FIGS. 4 and 5A-5B, the fabrication process 400 begins at 402 with a leadframe 502 as illustrated in the top and cross-sectional view taken along line 5B-5B in FIGS. 5A and 5B respectively. The leadframe 502 includes a die pad(s) 504 and leads comprised of inner leads 506 and outer leads 508 where the inner leads 506 and the outer leads 508 are connected. The inner leads 506 include a cross bar 510 integrated at a first (proximate) end 512. The cross bar 510 is substantially perpendicular to the inner leads 506. Thus, the inner leads 506 and cross bar 510 form a T-shape. The inner leads 506 are connected to the outer leads 508 and a dam bar 514 at a second (distal or terminal) end 516. The dam bars 514 are provided on the leadframe 502 to connect the inner leads 506 and the outer leads 508 together for support during fabrication.

The leadframe 502 further includes lead locks 518 disposed adjacent to the inner leads 506. The lead locks 518 are comprised of side supports 520 and openings 522, as described herein. Each side support 520 includes a first end 524 connected to the cross bar 510 and a second end 526 connected to the dam bars 514 (see FIG. 5C). The leadframe 502 further includes side rails 528 that connect the leadframe 502 to other leadframes to form an array of leadframes for fabrication processing.

At 404, the side supports 520 in the configuration in FIGS. 5A and 5B undergoes a partial etching process 420 between the first end 524 and second end 526 to form a recess 530 in the side supports 520, resulting in the configuration in FIGS. 5C and 5D. At 406, a die(s) 532 is attached to the die pad 504 via a die attach material 534 resulting in the configuration in FIGS. 5E and 5F. At 408, wire bonds 536 are attached from an active side 538 of the die(s) 532 to the inner leads 506, resulting in the configuration in FIGS. 5G and 5H. At 410, a mold compound 540 is added such that the mold compound 540 encapsulates the die pad(s) 504, the inner leads 506, the die(s) 532, and the wire bonds 536 resulting in the configuration in FIGS. 51 and 5J. The mold compound 540, however, does not encapsulate the outer leads 508. In other example IC packages, the mold compound 540 covers all but one surface of the leadframe 502, where the one surface not covered faces away from the die 532 and the electronic device. At 412, the outer leads 508 are shaped (formed) in a direction away from the active side 538 of the die(s) 532, as illustrated in FIG. 5K. At 414, the leadframes 502 are singulated (dam bars 514 and side rails 528 are removed) resulting in the electronic device 542 in FIG. 5K. After removal of the dam bars 514, the second end 526 of the side supports 520 is substantially flush with the mold compound 540 and is thus exposed. In addition, as illustrated in FIG. 1D, a width w of the side supports 520 is less than a width W of the outer leads 508.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a leadframe having at least one die pad, inner leads, and outer leads;
at least one die attached to the at least one die pad, the at least one die including an active side;
lead locks disposed adjacent to the inner leads, the lead locks having a side support disposed on each side of the inner leads and an opening defined between each side support and the inner leads;
wire bonds attached from the active side of the at least one die to the inner leads; and
a mold compound encapsulating the at least one die, the inner leads, the lead locks, and the wire bonds.

2. The electronic device of claim 1, wherein the inner leads include a cross bar integrated with a first end of the inner leads, the inner leads and the cross bar forming a T-shape.

3. The electronic device of claim 2, wherein each side support includes a first end and a second end, the first end being connected to the cross bar of the inner leads.

4. The electronic device of claim 3, wherein each side support of the lead locks are partially etched to form a recess between the first end and the second end of each side support.

5. The electronic device of claim 3, wherein the second end of each side support is substantially flush with the mold compound and is thereby exposed.

6. The electronic device of claim 1, wherein each side support is substantially parallel with the inner leads.

7. The electronic device of claim 1, wherein a width of each side support is less than a width of the outer leads.

8. The electronic device of claim 1, wherein the at least one die pad is a first die pad and the at least one die is a first die, the electronic device further including a second die pad and a second die attached to the second die pad.

9. The electronic device of claim 8, wherein the first die and the second die are attached to the first die pad and the second die pad via a die attach material.

10. A method comprising:
providing a leadframe, the leadframe including lead locks including side supports disposed on each side of inner leads of the leadframe and an opening defined between the side supports and the inner leads, a first end of the side supports being connected to a cross bar of the inner lead and a second end of the side supports being connected to a dam bar;
partially etching the side supports to form a recess between the first end to the second end of the side supports;
attaching at least one die to at least one die pad;
attaching wire bonds from an active side of the at least one die to the inner leads of the leadframe; and
forming a mold compound over the at least one die, the at least one die pad, the lead locks, and the wire bonds.

11. The method of claim 10, wherein the mold compound is formed through each opening and into the recess to thereby surround the inner leads and the side supports.

12. The method of claim 10, wherein the at least one die is a first die and the at least one die pad is a first die pad, the method further comprising attaching a second die to a second die pad.

13. The method of claim 10, further comprising shaping outer leads of the leadframe in a direction away from the active side of the at least one die.

14. The method of claim 13, further comprising removing side rails and dam bars from the leadframe to thereby separate the leadframe from an array of leadframes.

15. A multi-chip integrated circuit comprising:
a leadframe having a plurality of die pads, inner leads, and outer leads;
a plurality of dies, a die of the plurality of dies being attached to each die pad of the plurality of die pads, the plurality of dies having an active side;
lead locks disposed adjacent to the inner leads, the lead locks having a side support disposed on each side of the inner leads and an opening defined between each side support and the inner leads;
wire bonds attached from the active side of each of the plurality of dies to the inner leads; and
a mold compound encapsulating the plurality of dies, the inner leads, the lead locks, and the wire bonds.

16. The multi-chip integrated circuit of claim 15, wherein the inner leads include a cross bar integrated with a first end of the inner leads, the inner leads and cross bar forming a T-shape.

17. The multi-chip integrated circuit of claim 16, wherein each side support includes a first end and a second end, the first end being connected to the cross bar of the inner leads.

18. The multi-chip integrated circuit of claim 17, wherein each side support of the lead locks are partially etched to form a recess between the first end and the second end of each side support.

19. The electronic device of claim 17, wherein the second end of each side support is substantially flush with the mold compound and is thereby exposed.

20. The multi-chip integrated circuit of claim 15, wherein each side support is substantially parallel with the inner leads.
